(19) United States
(12) Patent Application Publication
(10) Pub. No.: US 2013/0293002 A1
(43) Pub. Date: Nov. 7, 2013

(54) DEVICE COMPRISING AN ELECTRONIC COMPONENT WITH HIGH SWITCHING SPEED

(71) Applicant: Alstom Transport SA, Levallois-Perret (FR)

(72) Inventors: Johnny BOU SAADA, Rixensart (BE); Fisal AL KAYAL, Rixensart (BE)

(73) Assignee: Alstom Transport SA, Levallois-Perret (FR)

(21) Appl. No.: 13/875,021

(22) Filed: May 1, 2013

(30) Foreign Application Priority Data
May 3, 2012 (FR) FR 12 54076

(51) Int. Cl. H03K 17/687

(52) U.S. Cl. CPC H03K 17/6871
USPC 307/9.1; 327/430

(57) ABSTRACT

An electrical switching device includes at least two electronic components, with a control circuit designed to control the or each component. Each component is connected to the control circuit by a respective connection, and each component has a switching speed that is higher than 10 kA/μs or higher than 20 kV/μs and wherein the or each connection has an inductance that is lower than 10 nH.

This claims the benefit of French Patent Application FR 12 54076, filed May 3, 2012 and hereby incorporated by reference herein.

The present invention relates to an electric switching device for an electronic component having a fast switching speed. The present invention is particularly applicable in the railway sector.

### BACKGROUND

At the present time, electronic components made of a semiconductor material with a wide band gap are being marketed. For example, components made of silicon carbide or gallium nitride are present on the market. These components involve lower losses and operate at a switching speed that is higher than components made with ordinary materials. In addition, their junction temperature is generally higher.

It is desirable to use such components in power converters because they offer a gain in terms of mass and volume and reduce electrical losses by a fairly significant degree.

Components made of silicon carbide are available for several components types like: diodes, transistors known as MOSFETs (acronym for Metal Oxyd Semi conductor Field Effect Transistors) or transistors of the type JFET (acronym for “Junction Field Effect Transistor”).

These components exist in various formats, whether it be in small packs (also known as “Packaging”) or in the form of a power module. In manner known per se, a power module generally consists of several components, for example in parallel.

Whatever be the form in which the component is sold, several imperatives are to be considered so as to be able to benefit from the advantages obtained through the use of these new components. In particular, the switching frequency used should be of the order of a few tens of kHz (kilohertz) in order to minimise the size of the passive components. The switching speed must also be high in order to minimise switching losses. In the context of this invention, a high switching speed is a switching speed of at least 10 kilo amps per microsecond (kA/μs) or 20 kilo volts per microsecond (kA/μs).

It is a known practice to use a component called IPM (acronym for Intelligent Power Module). In this case, all of the components are in a power module on which a part is moulded. This part contains the control circuit and is thus one single piece.

Nevertheless, with an IPM component according to the current design it is not possible to derive the full benefits of silicon carbide due to the problem of oscillation occurring between the control and the power semiconductor when the switching speed becomes high (greater than 10 kA/μs.)

### SUMMARY OF THE INVENTION

It is an object of the present invention to provide a device which makes it possible to benefit from the high switching speed of a fast switching electronic component.

The present invention provides an electric switching device comprising at least one electronic component and a control circuit designed to control the or each component. Each component is connected to the control circuit by a respective connection. The component has a switching speed that is higher than 10 kA/μs or higher than 20 kV/μs and the or each connection has an inductance that is lower than 10 nH.

The invention also concerns an electrical switching device comprising at least two electronic components and a control circuit designed to control the or each component. Each component is connected to the control circuit by a respective connection. Each component has a switching speed that is higher than 10 kA/μs or higher than 20 kV/μs and the or each connection has an inductance that is lower than 10 nH.

According to particular embodiments, the device comprises one or more of the following characteristic features, considered alone or in accordance with all technically possible combinations:

the component is made out of a material selected from amongst the group consisting of diamond, silicon carbide and gallium nitride

the control circuit includes a signal amplifier, the connection connecting the amplifier to the component,

the component is operative at a switching frequency that is between 1 kHz and 500 kHz,

the component is operative at a switching frequency between 10 kHz and 40 kHz,

the device comprises N components, N being an integer which is strictly greater than 1 and the circuit includes [(N+1)/2] control units, [(N+1)/2] of not an integer rounded down to be integer, each of the control units being connected to one or two electronic component(s),

the device comprises N components, N being an integer which is strictly greater than 1, and wherein the circuit includes N control units, each component being connected to a different unit,

the device comprises a plurality of connections, each connection having the same inductance more or less 3%,

the connection has an inductance that is lower than 5 nH,

the component has a switching speed that is higher than 15 kA/μs or 30 kV/μs,

the circuit comprises of several control units, which are synchronized with each other, and

the units are synchronized by connecting each of the outputs of the units to the same potential.

The invention also relates to a power converter comprising a device as previously described here above.

The object of the invention is also a railway vehicle having the power converter as previously described here above.

### BRIEF DESCRIPTION OF THE DRAWINGS

Other characteristic features and advantages of the invention will become apparent upon reading the detailed description provided below of an embodiment of the invention, given solely by way of example and with reference to the drawings as follows:

FIG. 1, is a schematic view of an example of an electrical switching device according to the invention,

FIG. 2, is a schematic view of another example of device,

FIG. 3, is a graph illustrating the result of a digital simulation for a device according to the state of the art,

FIG. 4, is a graph illustrating the result of another digital simulation based on a device according to the state of the art,

FIG. 5, is a graph illustrating the result obtained with a device according to the invention,

FIGS. 6 and 7, are graphs illustrating the results of the switching simulation for a device according to the state of the art, and

FIGS. 8 and 9, are graphs illustrating the results of the switching simulation for a device according to the invention.

### DETAILED DESCRIPTION

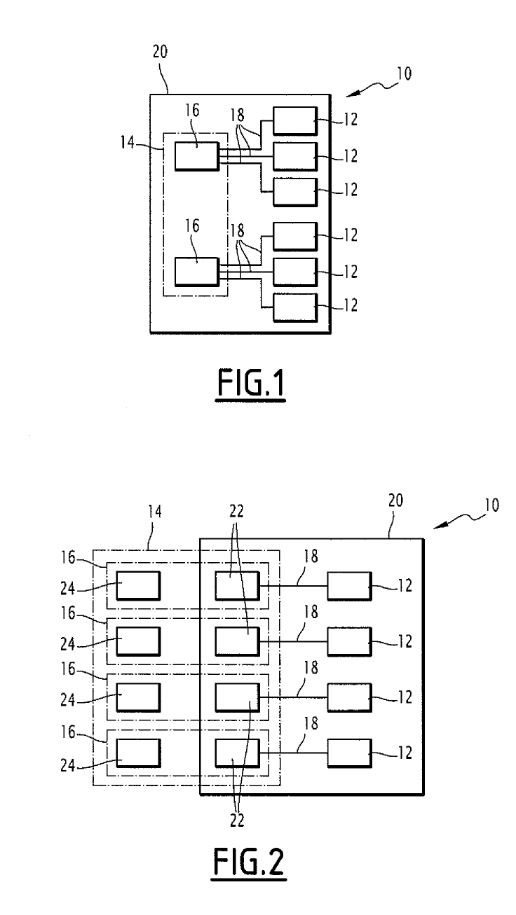

An electrical switching device 10 shown in FIG. 1 comprises six electronic components 12. The components 12 have a fast switching speed. The term fast switching speed is understood to mean a switching speed that is higher than 10 kA/μs or 20 kV/μs.

According to a preferred embodiment, the switching speed of the components 12 is greater than 15 kA/μs (respectively 30 kV/μs).

For example, components 12 made of diamond, silicon carbide or gallium nitride have a fast switching speed.

The components 12 are, by way of an illustration, a MOSFET transistor, a JFET transistor or any other electronic component having the aforementioned switching speed.

The device 10 also comprises a control circuit 14 or igniter. The control circuit 14 is used to control the components 12.

For example, the control circuit 14 is capable of transmitting an order that is imposed on the input “gate” of a transistor.

According to the example in FIG. 1, the control circuit 14 comprises a plurality of control units 16. In the case shown, the circuit 14 includes two units 16.

According to FIG. 1, in addition, the outputs of each of the units 16 are connected together. This implies that the outputs of all 16 the units are all at the same potential. In other words, the outputs deliver the same signal. Thus, optimal synchronisation of the units 16 is ensured.

Such synchronisation ensures that the control signal reaches all the components 12 at the same time. Thus, the power current is evenly distributed amongst all the components 12.

By way of a variant, these outputs are not connected together. In this case, the sequence of the ignition (or blocking) of each unit 16 is controlled so as to improve the balancing between the components 12 and to facilitate the fabrication of the device 10.

There again, via the sequence of ignition, in this variant, the control units 16 are synchronized with each other.

Each component 12 is joined to a unit 16 via a connection 18.

As is illustrated in FIG. 1, the connection 18 is of the wired type, it being understood that any type of connection providing for electrical conductivity between the component 12 and the associated unit 16 may be considered. By way of an illustration, these connections are made from aluminum wires (referred to by the generic English term “wire bonding”) or on printed circuit board (for example of the DBC type, DBC being the acronym for “Direct Bond Copper”). The length of these wires must be limited in order to be able to accelerate the switching speed without causing the control system to oscillate. A distance of 1 cm gives a wiring inductance of the order of 10 nH. This distance of 1 cm seems to be a good compromise between a high switching speed and a device 10 that may be produced for a reasonable manufacturing cost.

Each of the connections 18 has an inductance that is lower than 10 nH (nanohenries). Such an inductance value ensures the fast switching of the component 12 due to the fact that the circuit 14 is placed in the proximity of the controlled component 12.

Preferably the connections 18 all have the same inductance more or less 3% in order to ensure fast switching speed for all the components 12.

So as to further augmenting the quality of switching of the component, it is preferable for the inductance of the connection 18 to be lower than 5 nH.

In order to easily obtain such a low inductance for the connection 18, it is proposed according to FIG. 1 that the control circuit 14 be relatively close to the components 12. By close it is meant that the circuit 14 is at the very most about 10 mm away from each component 12.

Thus, the device 10 is presented in the form of a power module 20 incorporating the components 12 and the control circuit 14. A power module 20 in fact has restricted dimensions. According to the example in FIG. 1, there is a housing having the shape of a rectangular parallelepiped having edges none of which is greater than 12 cm. This integration offers the advantage of making the device compact.

For each of the units 16, at most three components 12 are associated with it. This allows for placing the components 12 relatively close to the units 16

By way of a variant, for a device 10 comprising N electronic components 12, it is advantageous to provide the control circuit 14 with:

[(N+1)/2] units 16 where [−] denotes the integer part.

In effect, each unit 16 is connected to a maximum of two components 12. Thus, the distance between the unit 16 and the components 12 to which the unit 16 is connected is greatly reduced.

Thus where the number N is an odd integer, the module 20 includes:

(N−1)/2+1 units 16.

(N−1)/2 units 16 are each connected to two components 12 and one single unit 16 is connected to a single component 12. This component 12 associated with the single unit is placed in the middle of the other components 12.

FIG. 2 illustrates another variant that makes it possible to obtain an associated inductance of a low value for each connection 18 between a component 12 and the unit 16.

According to this variant, each component 12 is associated with a control unit 16. According to this figure, the device 10 comprises only four components 12. The control circuit 14 thus comprises four units 16. Having a single control unit 16 per component 12 enables to ensure better control of the components 12.

Moreover, according to the example in FIG. 2, the units 16 comprise a first sub-unit 22 and a second sub-unit 24. The first sub-unit 22 includes elements of the unit 16 that have an effect on the proper functioning of the component 12 for high switching speeds. Thus, this sub unit 22 may be considered as the active part of the unit 16. By way of an example it has a signal amplifier. This first sub-unit 22 is placed in the module 20 so as to be in the proximity of the components 12.

The second sub-unit 24 is not integrated in the module 20. As a result thereof, the sub-unit 24 is at a further distance from the components 12 than the sub-unit 22. The sub-unit 24 comprises, for example, a DC-DC converter, the means for providing galvanic isolation, a defect management controller and means for ensuring other functions according to the various embodiments considered. In the embodiment shown in FIG. 1, the functions of the elements of the sub-unit 24 are far away because they have no influence on the proper functioning of the component 12 for high switching speeds. In particular the subunit 24 is at a distance that is greater than 10 cm from the module 20.

For this reason, in the module 20, only the sub unit 22 is present in the module 20.

During operation, the electrical switching device 10 benefits from the fast switching property of the component 12. The low value of the inductance of the connections 18 in the invention makes it possible to achieve this. In order to demonstrate this, various tests and simulations have been conducted.

Table 1 here below shows the results of tests carried out for several configurations. Configurations 1 and 2 are based on the state of the art while the configuration 3 is according to the invention. Table 1 indicates the associated performance levels for the switching. More specifically, the switching speed of the component 12 expressed in kA/μs and used for the test is given. The switching time is also given. This switching time is expressed in ns (nanoseconds). In addition, the switching power which corresponds to the switching losses is also given. It is expressed in mJ (milliJoules) and is measured in a configuration where the components operate at 750 V (volts) for 500 A (amps).

TABLE 1
influence of the variation in the inductance
on the switching speed of the component

| | Inductance | Switching | | |
|---|---|---|---|---|
| | of the | Speed of the | Switching | Switching |
| Configuration | connection | Component | Power | Time |
| considered | (nH) | (kA/μs) | (mJ) | (ns) |
| Configuration 1 | 1000 | 3.2 | 58.1 | 155 |
| Configuration 1 | 1000 | 3.0 | 61.9 | 165 |
| Configuration 2 | 100 | 7.0 | 26.6 | 71 |
| Configuration 2 | 100 | 6.5 | 28.9 | 77 |
| Configuration 3 | 10 | 11.1 | 16.9 | 45 |

The configuration 1 corresponds to a case where the control circuit is placed on the exterior of the module 20. This configuration corresponds to the conventional configuration for semiconductor devices having a relatively slow switching speed. In this case, the connection between the control circuit and the component is typically of the order of 1000 nH.

For configuration 1, it is observed to have, for a switching speed of about 3.0 kA/μs, losses of the order of 60 mJ and a switching time of the order of 160 ns. The switching speed is thus relatively low, with the switching time being slow and switching power at a significant level. It thus involves a limitation of the switching frequency and significant losses. As a consequence thereof, it is not possible to significantly reduce the size of passive components used in a power converter involving the use of components tested in configuration 1. For this reason, according to configuration 1, the converter that is comprised of the components 12 will be relatively heavy and expensive.

Configuration 2 according to the state of the art corresponds to the case of the IPM component previously described above. In this case, the inductance of the connection is lower by about 100 nH. The switching speed of the component is higher than in the case of configuration 1. In addition, in comparison to configuration 1, although the switching speed is faster (7.0 kA/μs), the switching power (26.6 mJ) and switching time (71 ns) are only about 50% of that in configuration 1.

The last case corresponds to that of the invention. In this case, the inductance of the connection is 10 nH. It is observed that, for a switching speed of 11.1 kA/μs for the components 12, the switching power amounts 17 mJ and the switching time amounts to only 45 ns. This shows that the use of an inductance reduced to 10 nH makes it possible to obtain good switching.

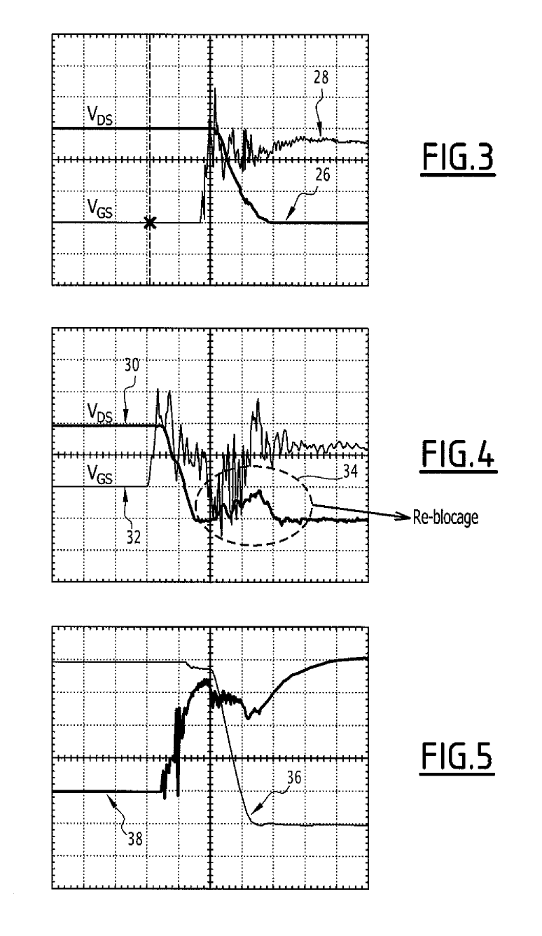

The results of other tests of a control circuit controlling a component 12 are presented in FIGS. 3, 4 and 5. In this case, the component 12 is a transistor, a power MOSFET which comprises, in a manner known per se, a drain, a source and a gate. The MOSFET transistor used is a MOSFET transistor made of silicon carbide, of the CRI brand (reference DMF 20 120 D). Each of the graphs in FIGS. 3, 4 and 5 shows the results of a test based on several configurations. The variable parameters are the inductance of the connection 18 between the control circuit 14 and the component 12 and to be controlled and the switching speed of the component 12.

According to the example in FIG. 3, the wiring inductance amounts to 100 nH between the control circuit and the MOSFET transistor. This corresponds in particular to configuration 2 in accordance with the state of the art. In the case of FIG. 3, the MOSFET transistor is controlled at a low switching speed of the order of 1.5 kV/μs. In FIG. 3 the evolutionary trends over time of the two curves 26 and 28 are represented in the form of an oscillogram (waveform diagram), the unit of time is 100 ns/tile.

The first curve 26 is a curve showing the change evolving over time of the voltage between the drain and source of the transistor. One tile represents 100 volts V. The second curve 28 is the curve of the change in the voltage between the gate and source of the transistor. This curve 28 is represented with an ordinate (y-coordinate) corresponding to 5 V/tile.

In the case of FIG. 3, between the command illustrated by the curve 28 and the output signal of the transistor, there does not appear to be any major distortion of the signal. This corresponds to the fact that at this low switching speed, the device is able to function.

FIG. 4 illustrates the variation over time obtained for the same configuration but at a higher switching speed, that is at 6 kV/μs.

FIG. 4 is also in the form of an oscillogram (waveform), whose unit of time is 50 ns/tile.

The variation over time of the voltage between the drain and the source is represented in the curve 30 while the curve 32 illustrates the variation over time of the voltage between the gate and source.

The unit of variation is not the same between the curves 30 and 32. For curve 32, one tile represents 10 V while for curve 30, one tile represents 100 V.

The most notable element of this FIG. 4 is the phenomenon of re-blocking observed in the encircled portion 34. The phenomena of re-blocking or re-ignition are linked to the resonance between the control circuit 14 and the transistor 12. The origin of these oscillations is the relatively high inductance of the connection between these two elements.

This indeed illustrates that in the configuration 2 according to the state of the art, it is not possible to increase the switching speed for it to exceed 10 kA/μs or 20 kV/μs. This is possible for a device 10 according to the invention. The experimental results obtained are shown in FIG. 5. There again, FIG. 5 is presented in the form of an oscillogram. The variation over time is represented with respect to the voltage between the drain and the source and the voltage between the gate and the source.

The curve 36 which corresponds to the voltage between the drain and the source is represented with the following units: 5 V/tile and 100 ns/tile on the abscissa (X axis). The curve 38 is represented with a scale of 100 V/tile on the ordinate (Y axis) and 100 ns/tile on the abscissa.

In this case, there are no oscillations observed corresponding to re-blocking. This shows that for a relatively low inductance, which is lower than 10 nH, the switching of the transistor 12 is stable and fast.

The results of FIGS. 3, 4 and 5 have been illustrated in the case where the control circuit 14 controls one single component 12.

In the case of a power module, several components (semiconductor chip) are arranged in parallel in order to form a switch that can withstand a much higher current.

According to the state of the art, a single control circuit 14 is used to control all the components arranged 12 in parallel and the associated connections 18 have varying inductances (variances greater than 3%) and of relatively large values (greater than 10 nH).

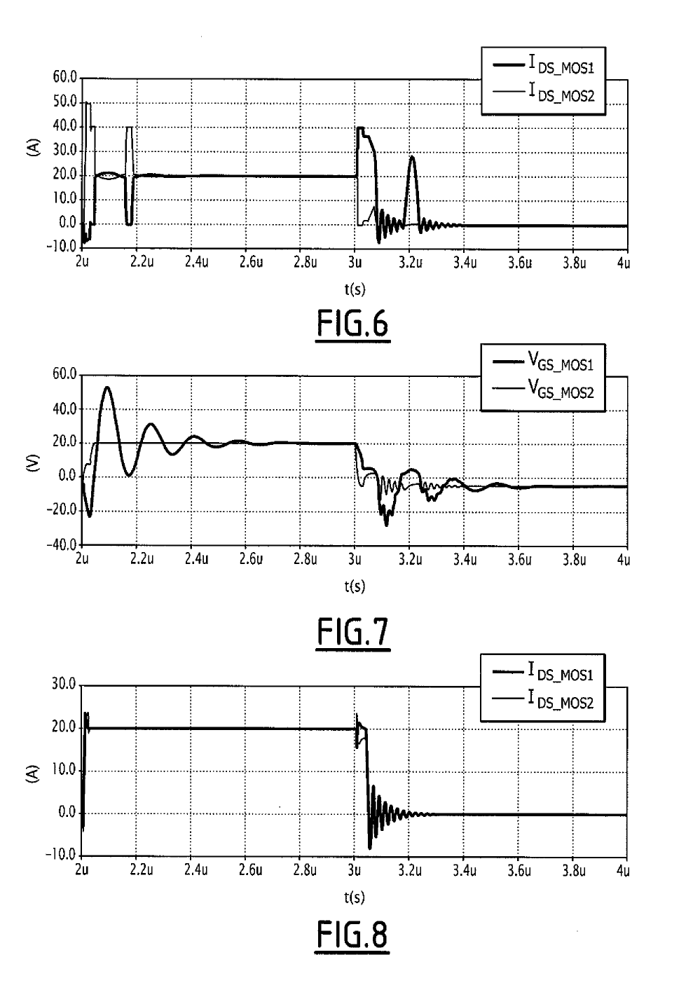

FIGS. 6 and 7 show the results of simulations of switching for two MOSFET type transistors 12 made of silicon carbide arranged in parallel when they are controlled by a single control circuit 14.

In these two FIGS. 6 and 7 is represented the variation over time of the current between the drain and the source of the component 12 as well as that of the voltage between the gate and source of the two transistors 12. Oscillations are observed over the curves of the currents and the voltages.

These oscillations are due to the differential inductance which is too large between the different connections 18 connecting the control circuit 14 and the components 12.

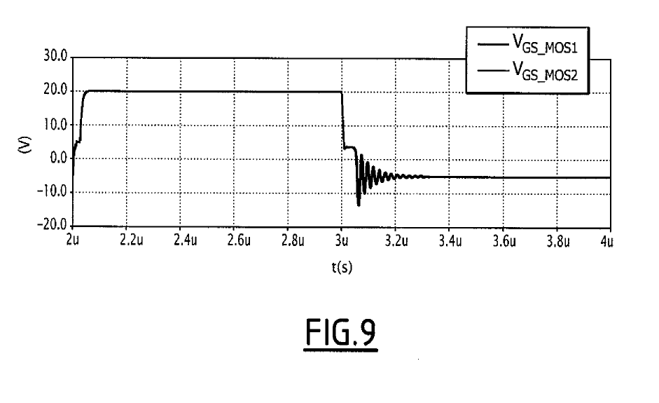

FIGS. 8 and 9 illustrate the same case as that in FIGS. 6 and 7, except that the configuration according to the invention is used. In this case, the switching speed of the components 12 can be made far more rapid because the behaviour of the fast switching module is stable.

Nevertheless, in these two FIGS. 8 and 9, it can be observed that there are still oscillations occurring on the curves of the currents and voltages. These oscillations correspond to the fact that there is still a residual inductance between the components 12 and the circuit 14. These oscillations begin to appear once the switching speed becomes greater than 12 kA/μs even if the inductance is very low.

This corresponds to the fact that it is preferable for the control units 16 to be synchronized. Such a synchronisation ensures that the control signal reaches all the components 12 at the same time. Thus, the power current is evenly distributed amongst all the components 12.

The advantage of the proposed invention is to optimise the switching of the power module 20 by using a very fast power semiconductor 12. In addition, the switching is also made stable.

This optimization makes it possible to raise the frequency of switching, and therefore allows for the use of other types of magnetic materials that are well suited for high frequency switching. Such materials make it possible so that the power converter as a whole has a smaller mass and a reduced volume. By way of an example, the weight of a silicon inverter for 50 kW (kilowatts) is of the order of 90 kg, while the same inverter made of silicon carbide makes up only 33% of this mass.

The proper use of silicon carbide also helps to reduce losses of power converters. As a consequence, the heat generated by the Joule effect decreases. The cooling system may then be less efficient. Due to this, it results in cost savings.

What is claimed is:

1. An electrical switching device comprising:
at least two electronic components; and
a control circuit designed to control at least one of the components, each component being connected to the control circuit by a respective connection, each component having a switching speed higher than 10 kA/μs or higher than 20 kV/μs and the connection having an inductance lower than 10 nH.

2. The device according to claim 1 wherein the components are made out of a material selected from the group consisting of diamond, silicon carbide and gallium nitride.

3. The device according to claim 1 wherein the control circuit includes a signal amplifier, the connection connecting the amplifier to the component.

4. The device according to claim 2 wherein the control circuit includes a signal amplifier, the connection connecting the amplifier to the component.

5. The device according to claim 1 wherein the components are operative at a switching frequency between 1 kHz and 500 kHz.

6. The device according to claim 2 wherein the components are operative at a switching frequency between 1 kHz and 500 kHz.

7. The device according to claim 3 wherein the components are operative at a switching frequency between 1 kHz and 500 kHz.

8. The device according to claim 5 wherein the components are operative at a switching frequency between 10 kHz and 40 kHz.

9. The device according to claim 6 wherein the components are operative at a switching frequency between 10 kHz and 40 kHz.

10. The device according to claim 7 wherein the components are operative at a switching frequency between 10 kHz and 40 kHz.

11. The device according to claim I wherein the device comprises N components, N being an integer which is strictly greater than 1 and the circuit includes [(N+1)12] control units where [(N+1)12] if not an integer is rounded down to the nearest integer, each of the control units being connected to one or two electronic component.

12. A device according to claim 2, wherein the device comprises N components, N being an integer which is strictly greater than 1 and the circuit includes [(N+1)/2] control units where [(N+1)/2] if not an integer is rounded down to the nearest integer, each of the control units being connected to one or two electronic component(s).

13. The device according to claim 1, wherein the device comprises N components, N being an integer which is strictly greater than 1, and wherein the circuit includes N control units, each component being connected to a different unit.

14. The device according to claims 1 wherein the device comprises a plurality of connections, each connection having a same inductance with 3% of each other.

15. The device according to claim 1 wherein the connection has an inductance that is lower than 5 nH.

16. The device according to claims 1 wherein each component has a switching speed that is higher than 15 kA/μs or 30 kV/μs.

17. The device according to claim 1 wherein the circuit comprises of a plurality of control units synchronized with each other.

18. The device according to claim 17 wherein each unit has an output and the units are synchronized by connecting each of the outputs of the units to the same potential

19. A power converter comprising the device according to claim 1.

20. A railway vehicle comprising the power converter according to claim 19.
